(19) United States
(12) Patent Application Publication
(10) Pub. No.: US 2026/0128718 A1
(43) Pub. Date: May 7, 2026

(54) HIGH-VOLTAGE SUPER-CASCODE STRUCTURES WITH SELF-PROTECTION CIRCUITRY

(71) Applicant: Cirrus Logic International Semiconductor Ltd., Edinburgh (GB)

(72) Inventors: Arashk NOROUZPOURSHIRAZI, Austin, TX (US); Eric J. KING, Austin, TX (US); John L. MELANSON, Austin, TX (US)

(73) Assignee: Cirrus Logic International Semiconductor Ltd., Edinburgh (GB)

(21) Appl. No.: 19/343,234

(22) Filed: Sep. 29, 2025

Related U.S. Application Data
(60) Provisional application No. 63/716,543, filed on Nov. 5, 2024.

(30) Foreign Application Priority Data
Nov. 20, 2024 (GB) 2417069.8

(51) Int. Cl. H03F 1/52; H03F 3/24

(52) U.S. Cl. CPC H03F 1/52; H03F 3/245; H03F 2200/426

(57) ABSTRACT

A cascode structure may include a switching path comprising a main N-type field effect transistor switching device having a first gate and a cascode switching N-type field effect transistor device in series with the main N-type field effect transistor switching device and having a second gate and a circuit coupled between the first gate and the second gate. The circuit may be configured to in an off-state of the switching path, provide a high-impedance path between the first gate and the second gate, such that the second gate is switched to a protection voltage as high as a drain-to-source breakdown voltage of the main N-type field effect transistor switching device and such that the switching path is able to tolerate as high as the sum of the drain-to-source breakdown voltages of the main N-type field effect transistor switching device and the cascode switching N-type field effect transistor device.

### RELATED APPLICATIONS

The present disclosure claims priority to U.S. Provisional Patent Application Ser. No. 63/716,543, filed Nov. 5, 2024, and United Kingdom Patent Application No. 2417069.8, filed Nov. 20, 2024, each of which is incorporated by reference herein in its entirety.

### FIELD OF DISCLOSURE

The present disclosure relates in general to charge pumps, including without limitation those used in personal audio devices such as wireless telephones and media players, and more specifically, to high-voltage cascode structures having self-protection circuitry which are used in charge pumps.

### BACKGROUND

Personal audio devices, including wireless telephones, such as mobile/cellular telephones, cordless telephones, mp3 players, and other consumer audio devices, are in widespread use. Such personal audio devices may include circuitry for driving a pair of headphones or one or more speakers. Such circuitry often includes a power amplifier for driving an audio output signal to headphones or speakers, and the power amplifier may often be the primary consumer of power in a personal audio device, and thus, may have the greatest effect on the battery life of the personal audio device. In devices having a linear power amplifier for the output stage, power is wasted during low signal level outputs, because the voltage drop across the active output transistor plus the output voltage will be equal to the constant power supply rail voltage. Therefore, amplifier topologies such as Class-G and Class-H are desirable for reducing the voltage drop across the output transistor(s) and thereby reducing the power wasted in dissipation by the output transistor(s).

In order to provide a variable power supply voltage to such a power amplifier, a charge pump power supply may be used, for example such as that disclosed in U.S. Pat. No. 8,311,243, in which an indication of the signal level at the output of the circuit is used to control the power supply voltage in a Class-G topology. The above-described topology may raise the efficiency of the audio amplifier, in general, as long as periods of low signal level are present in the audio source. Typically in such topologies, a plurality of thresholds define output signal level-dependent operating modes for the charge pump power supply, wherein a different supply voltage is generated by the charge pump power supply in each mode.

In a typical switching charge pump, metal-oxide semiconductor field-effect transistors (MOSFETs) used to implement switches may have breakdown voltages that limit the amount of power that may be transferred through the MOSFETs. Accordingly, charge pumps for structures that mitigate the limitations of transistor breakdown voltages may be desired.

### SUMMARY

In accordance with the teachings of the present disclosure, certain disadvantages and problems associated with performance of charge pumps have been reduced or eliminated.

In accordance with embodiments of the present disclosure, a cascode structure may include a switching path comprising a main N-type field effect transistor switching device having a first gate and a cascode switching N-type field effect transistor device in series with the main N-type field effect transistor switching device and having a second gate and a circuit coupled between the first gate and the second gate. The circuit may be configured to in an off-state of the switching path, provide a high-impedance path between the first gate and the second gate, such that the second gate is switched to a protection voltage as high as a drain-to-source breakdown voltage of the main N-type field effect transistor switching device and such that the switching path is able to tolerate as high as the sum of the drain-to-source breakdown voltages of the main N-type field effect transistor switching device and the cascode switching N-type field effect transistor device. The circuit may also be configured to in an on-state of the switching path, provide a low-impedance path between the first gate and the second gate, such that a first voltage on the first gate and a second voltage on the second gate are approximately equal and the circuit is controlled by a voltage at a drain of the main N-type field effect transistor switching device.

In accordance with these and other embodiments of the present disclosure, a cascode structure may include a switching path comprising a main P-type field effect transistor switching device having a first gate and a cascode switching P-type field effect transistor device in series with the main P-type field effect transistor switching device and having a second gate and a circuit coupled between the first gate and the second gate. The circuit may be configured to in an off-state of the switching path, provide a high-impedance path between the first gate and the second gate, such that the second gate is switched to a protection voltage as high as a drain-to-source breakdown voltage of the main P-type field effect transistor switching device and such that the switching path is able to tolerate as high as the sum of the drain-to-source breakdown voltages of the main P-type field effect transistor switching device and the cascode switching P-type field effect transistor device. The circuit may also be configured to in an on-state of the switching path, provide a low-impedance path between the first gate and the second gate, such that a first voltage on the first gate and a second voltage on the second gate are approximately equal and the circuit is controlled by a voltage at a drain of the main P-type field effect transistor switching device.

In accordance with these and other embodiments of the present disclosure, a method may be provided in a cascode structure having a switching path comprising a main N-type field effect transistor switching device having a first gate and a cascode switching N-type field effect transistor device in series with the main N-type field effect transistor switching device and having a second gate. The method may include, with a circuit coupled between the first gate and the second gate, in an off-state of the switching path, providing a high-impedance path between the first gate and the second gate, such that the second gate is switched to a protection voltage as high as a drain-to-source breakdown voltage of the main N-type field effect transistor switching device and such that the switching path is able to tolerate as high as the sum of the drain-to-source breakdown voltages of the main N-type field effect transistor switching device and the cascode switching N-type field effect transistor device. The method may further include, with the circuit, in an on-state of the switching path, providing a low-impedance path between the first gate and the second gate, such that a first voltage on the first gate and a second voltage on the second gate are approximately equal and the circuit is controlled by a voltage at a drain of the main N-type field effect transistor switching device.

In accordance with these and other embodiments of the present disclosure, a method may be provided in a cascode structure having a switching path comprising a main P-type field effect transistor switching device having a first gate and a cascode switching P-type field effect transistor device in series with the main P-type field effect transistor switching device and having a second gate. The method may include, with a circuit coupled between the first gate and the second gate, in an off-state of the switching path, providing a high-impedance path between the first gate and the second gate, such that the second gate is switched to a protection voltage as high as a drain-to-source breakdown voltage of the main P-type field effect transistor switching device and such that the switching path is able to tolerate as high as the sum of the drain-to-source breakdown voltages of the main P-type field effect transistor switching device and the cascode switching P-type field effect transistor device. The method may further include, with the circuit, in an on-state of the switching path, providing a low-impedance path between the first gate and the second gate, such that a first voltage on the first gate and a second voltage on the second gate are approximately equal and the circuit is controlled by a voltage at a drain of the main P-type field effect transistor switching device.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the example, present embodiments and certain advantages thereof may be acquired by referring to the following description taken in conjunction with the accompanying drawings, in which like reference numbers indicate like features, and wherein:

FIG. 1 is a circuit diagram of selected components of an example charge pump, in accordance with embodiments of the present disclosure;

FIG. 2 is a circuit diagram of selected components of an example low-side N-type FET channel path within the example charge pump of FIG. 1, in accordance with embodiments of the present disclosure;

FIG. 3 is a graph depicting example waveforms for voltages at various nodes of the low-side N-type FET channel path depicted in FIG. 2, in accordance with embodiments of the present disclosure;

FIG. 4 is a circuit diagram of selected components of an example low-side N-type FET channel path and a high-side N-type FET channel path that may be used in lieu of a high-side P-type FET channel path within the example charge pump of FIG. 1, in accordance with embodiments of the present disclosure;

FIG. 5 is a circuit diagram of selected components of an example low-side N-type FET channel path and another high-side N-type FET channel path that may be used in lieu of a high-side P-type FET channel path within the example charge pump of FIG. 1, in accordance with embodiments of the present disclosure;

FIG. 6 is a circuit diagram of selected components of an example low-side N-type FET channel path and yet another high-side N-type FET channel path that may be used in lieu of a high-side P-type FET channel path within the example charge pump of FIG. 1, in accordance with embodiments of the present disclosure;

FIG. 7 is a circuit diagram of selected components of another example low-side N-type FET channel path within the example charge pump of FIG. 1, in accordance with embodiments of the present disclosure; and

FIG. 8 is a circuit diagram of selected components of yet another example low-side N-type FET channel path within the example charge pump of FIG. 1, in accordance with embodiments of the present disclosure.

### DETAILED DESCRIPTION

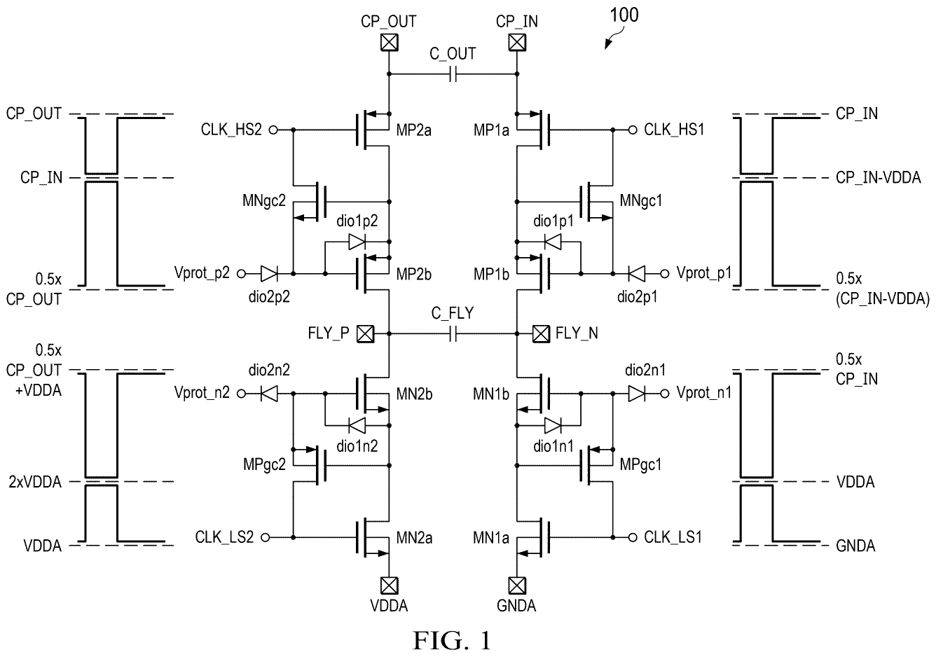

FIG. 1 is a circuit diagram of selected components of an example charge pump 100, in accordance with embodiments of the present disclosure. As shown in FIG. 1, charge pump 100 may have an input pin having an input voltage CP_IN, an output pin having an output voltage CP_OUT, a supply pin with a supply voltage VDDA, a ground pin with a ground voltage GNDA, a positive flying capacitor pin having positive flying capacitor voltage FLY_P, and a negative flying capacitor pin having negative flying capacitor voltage FLY_N.

A high-side cascode structure comprising a P-type field-effect transistor (FET) MP1a in series with a P-type FET MP1b may be coupled between input voltage CP_IN and negative flying capacitor voltage FLY_N. Similarly, a high-side cascode structure comprising a P-type FET MP2a in series with a P-type FET MP2b may be coupled between output voltage CP_OUT and positive flying capacitor voltage FLY_P. Further, a low-side cascode structure comprising an N-type FET MN1a in series with an N-type FET MN1b may be coupled between ground voltage GNDA and negative flying capacitor voltage FLY_N. Similarly, a low-side cascode structure comprising an N-type FET MN2a in series with an N-type FET MN2b may be coupled between supply voltage VDDA and positive flying capacitor voltage FLY_P. In some embodiments, each of FETs MP1a, MP1b, MP2a, MP2b, MN1a, MN1b, MN2a, and MN2b may be implemented using lateral-diffusion metal-oxide-semiconductor (LDMOS) FETs.

An output capacitor C_OUT may be coupled between input voltage CP_IN and output voltage CP_OUT. Further, a flying capacitor C_FLY may be coupled between positive flying capacitor voltage FLY_P and negative flying capacitor voltage FLY_N.

Each cascode structure may have its FETs biased by one of a clock voltage and a protection voltage. For example, P-type FET MP1a may be clocked with a clock signal CLK_HS1 which may pulse between input voltage CP_IN and a voltage equal to the difference of input voltage CP_IN and supply voltage VDDA, as shown in FIG. 1. P-type FET MP1b may be source-biased and gate-biased by a protection circuit. Such protection circuit may include a diode dio1p1 with its anode coupled to the gate of P-type FET MP1b and its cathode coupled to the source of P-type FET MP1b. Further, a diode dio2p1 may receive a protection voltage Vprot_p1 at its anode and may have its cathode coupled to the gate of P-type FET MP1b. The gate voltage of P-type FET MP1b may pulse in an opposite direction as clock signal CLK_HS1 between the difference of input voltage CP_IN and supply voltage VDDA and protection voltage Vprot_p1, which protection voltage Vprot_p1 may be equal to a ratio (e.g., 0.5) of such difference as shown in FIG. 1. In addition, an N-type FET MNgc1 may be coupled at its drain terminal to clock signal CLK_HS1, coupled at its source terminal to the gate terminal of P-type FET MP1b, and coupled at its gate terminal to the electrical node common to P-type FET MP1a and P-type FET MP1b.

Similarly, P-type FET MP2a may be clocked with a clock signal CLK_HS2 which may pulse between input voltage CP_IN and output voltage CP_OUT, as shown in FIG. 1. P-type FET MP2b may be source-biased and gate-biased by a protection circuit. Such protection circuit may include a diode dio1p2 with its anode coupled to the gate of P-type FET MP2b and its cathode coupled to the source of P-type FET MP2b. Further, a diode dio2p1 may receive a protection voltage Vprot_p2 at its anode and may have its cathode coupled to the gate of P-type FET MP2b. The gate voltage of P-type FET MP2b may pulse in an opposite direction as clock signal CLK_HS2 between input voltage CP_IN and protection voltage Vprot_p2, which protection voltage Vprot_p2 may be equal to a ratio (e.g., 0.5) of output voltage VP_OUT as shown in FIG. 1. In addition, an N-type FET MNgc2 may be coupled at its drain terminal to clock signal CLK_HS2, coupled at its source terminal to the gate terminal of P-type FET MP2b, and coupled at its gate terminal to the electrical node common to P-type FET MP2a and P-type FET MP2b.

As another example, N-type FET MN1a may be clocked with a clock signal CLK_LS1 which may pulse between ground voltage GNDA and supply voltage VDDA, as shown in FIG. 1. N-type FET MN1b may be source-biased and gate-biased by a protection circuit. Such protection circuit may include a diode dio1n1 with its cathode coupled to the gate of N-type FET MN1b and its anode coupled to the source of N-type FET MN1b. Further, a diode dio2n1 may receive a protection voltage Vprot_n1 at its cathode and may have its anode coupled to the gate of N-type FET MN1b. The gate voltage of N-type FET MN1b may pulse in an opposite direction as clock signal CLK_LS1 between supply voltage VDDA and protection voltage Vprot_n1, which protection voltage Vprot_n1 may be equal to a ratio (e.g., 0.5) of input voltage CP_IN as shown in FIG. 1. In addition, a P-type FET MPgc1 may be coupled at its drain terminal to clock signal CLK_LS1, coupled at its source terminal to the gate terminal of N-type FET MN1b, and coupled at its gate terminal to the electrical node common to N-type FET MN1a and N-type FET MN1b.

Similarly, N-type FET MN2a may be clocked with a clock signal CLK_LS2 which may pulse between supply voltage VDDA and a multiple (e.g., 2) of supply voltage VDDA, as shown in FIG. 1. N-type FET MN2b may be source-biased and gate-biased by a protection circuit. Such protection circuit may include a diode dio1n2 with its cathode coupled to the gate of N-type FET MN2b and its anode coupled to the source of N-type FET MN2b. Further, a diode dio2n2 may receive a protection voltage Vprot_n2 at its cathode and may have its anode coupled to the gate of N-type FET MN2b. The gate voltage of N-type FET MN2b may pulse in an opposite direction as clock signal CLK_LS2 between the ratio (e.g., 2) of supply voltage VDDA and protection voltage Vprot_n2, which protection voltage Vprot_n2 may be equal to the sum of a ratio (e.g., 0.5) of output voltage CP_OUT and supply voltage VDDA as shown in FIG. 1. In addition, a P-type FET MPgc2 may be coupled at its drain terminal to clock signal CLK_LS2, coupled at its source terminal to the gate terminal of N-type FET MN2b, and coupled at its gate terminal to the electrical node common to N-type FET MN2a and N-type FET MN2b.

The cascode structures described above may extend the effective breakdown voltage of each switching path of charge pump 100 to double the breakdown voltage allowed by each FET in the path.

While a ratio of 0.5 is used to create the various protection voltages Vprot_p1, Vprot_p2, Vprot_n1, and Vprot_n2, any other ratio between 0 and 1 may be used (with the addition of supply voltage VDDA where appropriate) to protect the drain-gate/source of FETs and prevent forward-basing of protection diodes dio2p1, dio2p2, dio2n1, and dio2n2. In some embodiments, depending on the relation of input voltage CP_IN and source voltage VDDA, more combinations of the protection voltages may be used to ensure these conditions. Protection voltages Vprot_p1, Vprot_p2, Vprot_n1, and Vprot_n2 may be created in any suitable manner, including by combinations of resistor ladders, source-follower buffers, op amp buffers, etc.

In effect, each of P-type FET MPgc1, P-type FET MPgc2, N-type FET MNgc1, and N-type FET MNgc2 may implement a circuit, wherein such circuit may, in an off-state of a switching path, provide a high-impedance path between a first gate of a main switching device (e.g., P-type FET MP1a, P-type FET MP2a, N-type FET MN1a, N-type FET MP2a) and a second gate of a cascode switching device (e.g., P-type FET MP1b, P-type FET MP2b, N-type FET MN1b, N-type FET MP2b), such that the second gate is switched to a protection voltage as high as a drain-to-source breakdown voltage of the main switching device, and such that the switching path is able to tolerate as high as the sum of the drain-to-source breakdown voltages of the main switching device and the cascode switching device. Further, in an on-state of the switching path, the circuit may provide a low-impedance path between the first gate and the second gate, such that a first voltage on the first gate and a second voltage on the second gate are approximately equal and the circuit (e.g., via the gate of P-type FET MPgc1, P-type FET MPgc2, N-type FET MNgc1, or N-type FET MNgc2) is controlled by a voltage at a drain of the main switching device.

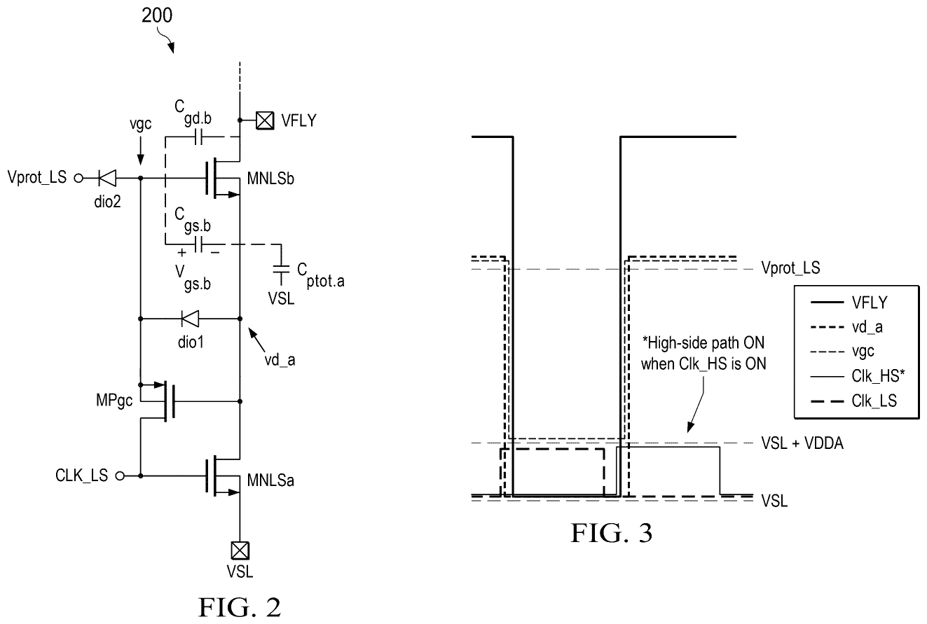

FIG. 2 is a circuit diagram of selected components of an example low-side N-type FET channel path 200 within the example charge pump of FIG. 1, in accordance with embodiments of the present disclosure. N-type FET channel path 200 is representative of one of the N-type FET cascode structures of charge pump 100 and its associated protection circuit, and depicts parasitic capacitances not shown in FIG. 1. As shown in FIG. 2, low-side N-type FET channel path 200 may include a low-side cascode structure comprising an N-type FET MNLSa (analogous to N-type FETs MN1a and MN2a of FIG. 1) in series with an N-type FET MPLSb (analogous to N-type FETs MN1b and MN2b of FIG. 1) and may be coupled between a low-side source voltage VSL (analogous to ground voltage GNDA and source voltage VDDA) and a flying capacitor voltage VFLY (analogous to negative flying capacitor voltage FLY_N and positive flying capacitor voltage FLY_P). N-type FET MNLSa may be clocked with a clock signal CLK_LS (analogous to clock signals CLK_LS1 and CLK_LS2) which may pulse between source voltage VSL and the sum of supply voltage VSL and supply voltage VDDA, as shown in FIG. 3. N-type FET MNLSb may be source-biased and gate-biased by a protection circuit. Such protection circuit may include a diode dio1 (analogous to diodes dio1n1 and dio1n2) with its cathode coupled to the gate of N-type FET MNLSb and its anode coupled to the source of N-type FET MNLSb. Further, a diode dio2 (analogous to diodes dio2n1 and dio2n2) may receive a protection voltage Vprot_LS (analogous to protections voltages Vprot_n1 and Vprot_n2) at its cathode and may have its anode coupled to the gate of N-type FET MNLSb. In addition, a P-type FET MPgc (analogous to P-type FETs MPgc1 and MPgc2) may be coupled at its drain terminal to clock signal CLK_LS, coupled at its source terminal to the gate terminal of N-type FET MNLSb, and coupled at its gate terminal to the electrical node common to N-type FET MNLSa and N-type FET MNLSb.

In operation, upon low-side N-type FET channel path 200 turning on (i.e., CLK_LS=ON), voltage vd_a on the electrical node common to N-type FETs MNLSa and MNLSb may be pulled down to supply voltage VSL resulting in P-type FET MPgc turning on and pulling down a voltage vgc on the gate terminal MNLSb to the voltage of clock signal CLK_LS (i.e., VSL+VDDA). In this phase of operation, diodes dio1 and dio2 may be reverse-biased and both N-type FETs MNLSa and MNLSb may conduct, pulling flying capacitor voltage VFLY down to supply voltage VSL. Upon the high-side path turning on (i.e., clock signal CLK_HS1 or CLK_HS2 being ON), flying capacitor voltage VFLY may be pulled up to either input voltage CP_IN or output voltage CP_OUT, which may pull up voltage vgc via gate-drain parasitic capacitance C_{gd,b} of N-type FET MNLSb until voltage vgc is clamped by diode dio2 to protection voltage Vprot_LS. Assuming that P-type-FET MPgc may be smaller than N-type FETs MNLSa and MNLSb, and the fact that a voltage across parasitic capacitance C_{gd,b} may be limited to the gate-source of N-type FET MNLSb in its off state, parasitic capacitance C_{gd,b} may direct most of its dynamic current during this transition through diode dio2 to protection voltage Vprot_LS. Consequently, voltage vd_a may be charged to approximately protection voltage Vprot_LS by N-type FET MNLSb, and diode dio1 may prevent voltage vd_a from being pulled higher than protection voltage Vprot_LS due to additional leakage currents.

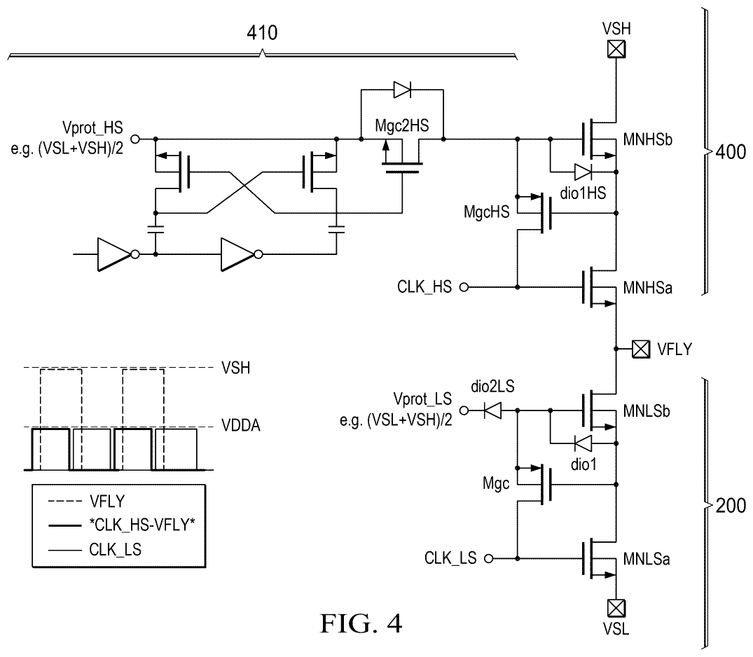

It may be desirable to use N-type FETs in lieu of high-side P-type FETs MP1a, MP1b, MP2a, and MP2b. To that end, FIG. 4 is a circuit diagram of selected components of example low-side N-type FET channel path 200 and a high-side N-type FET channel path 400 that may be used in lieu of a high-side P-type FET channel path within charge pump 100, in accordance with embodiments of the present disclosure.

As shown in FIG. 4, high-side N-type FET channel path 400 may include a high-side cascode structure comprising an N-type FET MNHSa in series with an N-type FET MNHSb and may be coupled between a high-side source voltage VSH (analogous to input voltage CP_IN and output voltage CP_OUT) and flying capacitor voltage VFLY (analogous to negative flying capacitor voltage FLY_N and positive flying capacitor voltage FLY_P). N-type FET MNHSa may be clocked with a clock signal CLK_HS (analogous to clock signals CLK_HS1 and CLK_HS2), which may track flying capacitor voltage VFLY as its negative supply. N-type FET MNHSb may be source-biased and gate-biased by a protection circuit which may be substantially different than that depicted in FIG. 1. Such protection circuit may include a diode dio1HS (analogous to diodes dio1p1 and dio1p2) with its anode coupled to the gate of N-type FET MNHSb and its cathode coupled to the source of N-type FET MNHSb. Further, the protection circuit for high-side N-type FET channel path 400 may employ a bootstrap driver 410 to drive the gate of N-type FET MNHSb.

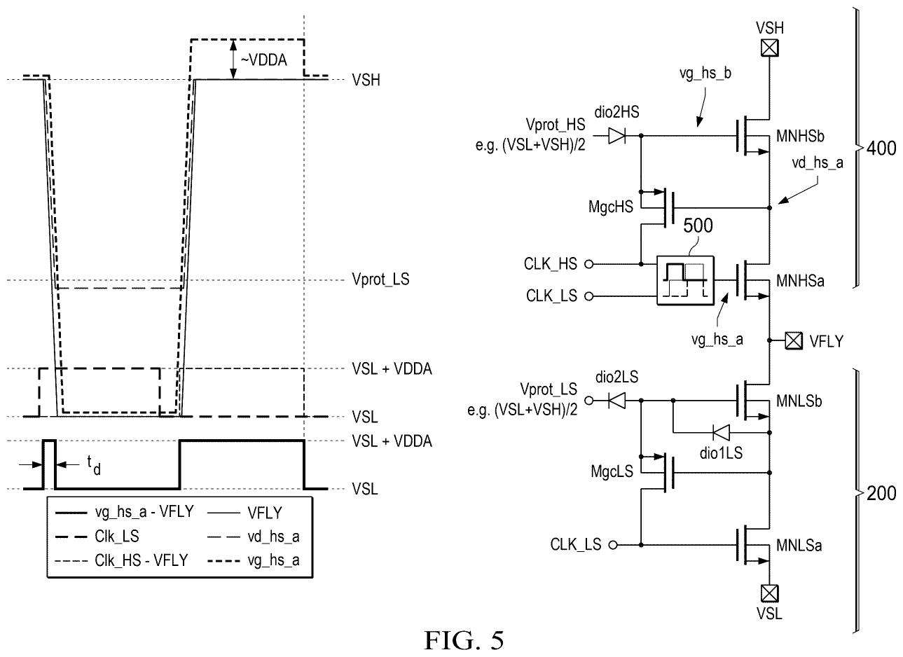

FIG. 5 is a circuit diagram of selected components of example low-side N-type FET channel path 200 and a high-side N-type FET channel path 400 that may be used in lieu of a high-side P-type FET channel path within charge pump 100, in accordance with embodiments of the present disclosure. FIG. 5 depicts an alternative approach to that depicted in FIG. 4, such that bootstrap driver 410 may not be needed. In the approach of FIG. 5, a logic element 500, which may comprise a clocked delay circuit comprising digital logic and delay cells, may create a delay pulse with duration t_{d} on a gate voltage vg_hs_a on the gate of N-type FET MNHSa as a function of the rising edge of clock signal CLK_LS.

To further describe the circuit of FIG. 5, upon pulling down of flying capacitor voltage VFLY by low-side N-type FET channel path 200 (i.e., at the rising edge of clock signal CLK_LS), gate voltage vgs_hs_a may be pulled down with a delay with respect to the falling edge of flying capacitor voltage VFLY. Consequently, N-type FET MNHSa may temporarily turn on to conduct, pulling down source voltage vd_hs_a on the source terminal of N-type FET MNHSb and a gate voltage vg_hs_b may also be pulled down by the source of P-type FET MgcHS until gate voltage vg_hs_b is clamped by diode dio2HS. Such high-side pulse may be combined with clock signal CLK_HS to assist the pull down of high-side N-type FET channel path 400 upon the rising edge of clock signal CLK_LS. The duration t_{d} of the pulse may be set based on any suitable circuit parameters (e.g., device sizes).

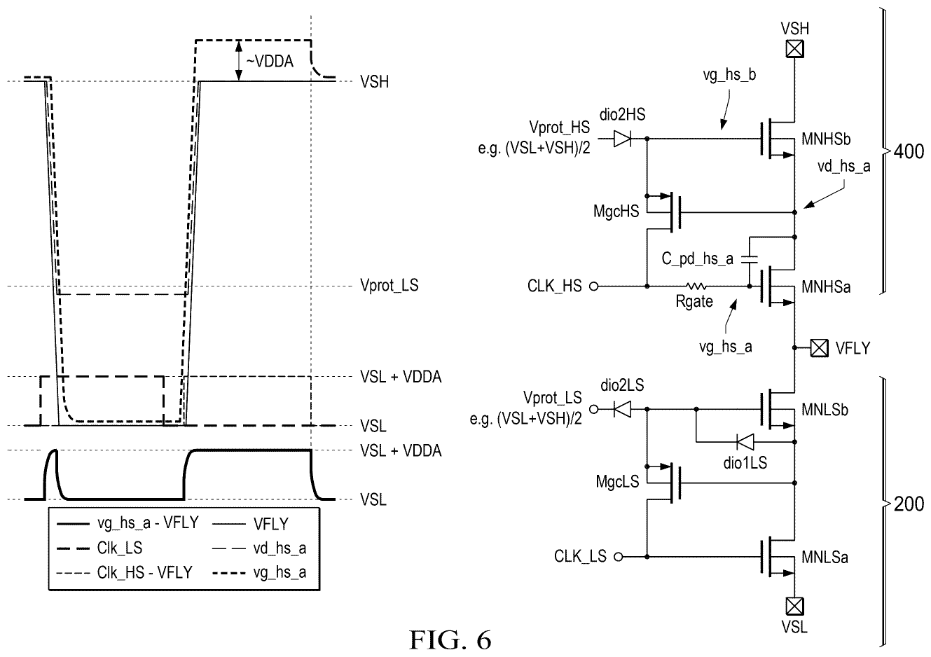

As a similar alternative, FIG. 6 is a circuit diagram of selected components of example low-side N-type FET channel path 200 and a high-side N-type FET channel path 400 that may be used in lieu of a high-side P-type FET channel path within charge pump 100, in accordance with embodiments of the present disclosure. The approach of FIG. 6 is similar in many respects to that of FIG. 5, except that a gate resistor Rgate may be interfaced between clock signal CLK_HS and the gate of N-type FET MNHSa (e.g., in lieu of logic element 500) to, together with a Miller capacitance C_{gd,hsa} of N-type FET MNHSa, create a delay pulse on a gate voltage vg_hs_a on the gate of N-type FET MNHSa as a function of the falling edge of clock signal CLK_LS, albeit indirectly in response to the falling edge of flying capacitor voltage VFLY.

In other words, in FIG. 6, upon pull down of flying capacitor voltage VFLY by low-side N-type FET channel path 200 (i.e., at the rising edge of clock signal CLK_LS), gate voltage vg_hs_a may be pulled down with a delay with respect to flying capacitor voltage VFLY, while clock signal CLK_HS is pulled down and floats with respect to flying capacitor voltage VFLY. The amplitude and duration of the pulse on gate voltage vg_hs_a may be controlled by a resistance of gate resistor Rgate, given its interaction with Miller capacitance C_{gd,hsa} during the high-to-low transition of flying capacitor voltage VFLY.

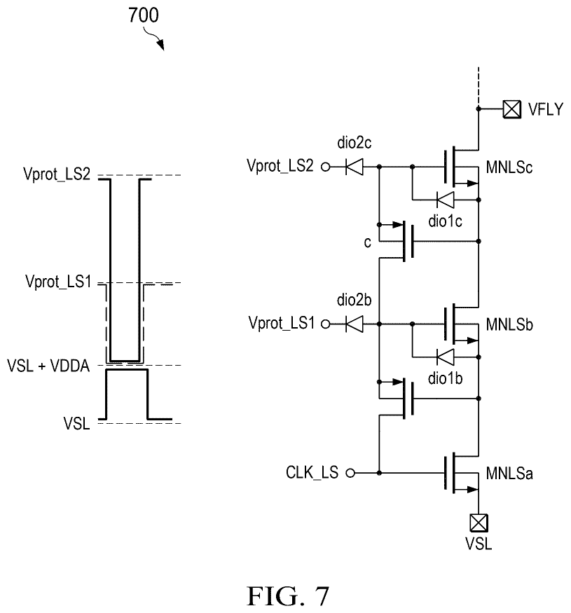

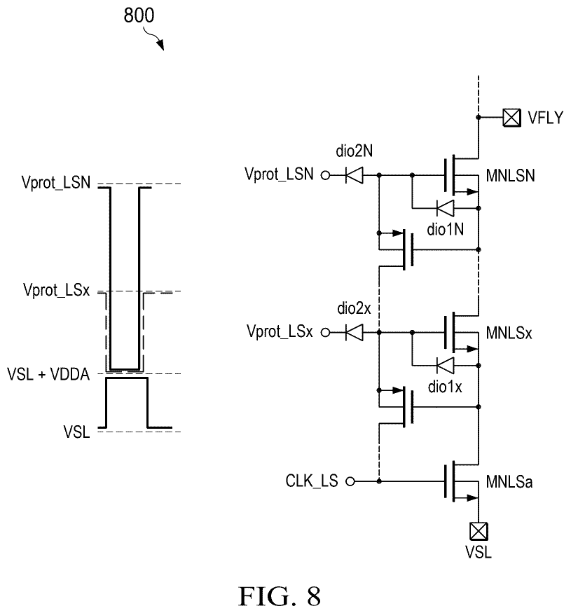

The proposed cascode structures described above may be used in a modular fashion to extend the effective breakdown voltage of the switching path by including more than two series FETs, as shown in FIGS. 7 and 8. FIG. 7 depicts an example low-side N-type FET channel path 700 within the example charge pump of FIG. 1, in accordance with embodiments of the present disclosure, in which low-side N-type FET channel path 700 includes three N-type FETs MNLSa, MNLSb, and MNLSc. FIG. 8 is a circuit diagram of selected components of yet another example low-side N-type FET channel path 800 within the example charge pump of FIG. 1, in accordance with embodiments of the present disclosure, in which low-side N-type FET channel path 800 includes a suitable plurality of N-type FETs MNLSa, . . . , MNLSx, . . . , and MNLSN. Techniques analogous to those shown in FIGS. 7 and 8 may also be applied to a high-side P-type FET switching path. Further, techniques analogous to those shown in FIGS. 7 and 8 may also be applied to a high-side N-type FET switching path, wherein a delay element may only be needed at the gate of N-type FET MNHSa.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A cascode structure comprising:
a switching path comprising:
a main N-type field effect transistor switching device having a first gate; and
a cascode switching N-type field effect transistor device in series with the main N-type field effect transistor switching device and having a second gate; and
a circuit coupled between the first gate and the second gate, wherein the circuit is configured to:
in an off-state of the switching path, provide a high-impedance path between the first gate and the second gate, such that the second gate is switched to a protection voltage as high as a drain-to-source breakdown voltage of the main N-type field effect transistor switching device and such that the switching path is able to tolerate as high as the sum of the drain-to-source breakdown voltages of the main N-type field effect transistor switching device and the cascode switching N-type field effect transistor device; and
in an on-state of the switching path, provide a low-impedance path between the first gate and the second gate, such that a first voltage on the first gate and a second voltage on the second gate are approximately equal and the circuit is controlled by a voltage at a drain of the main N-type field effect transistor switching device.

2. The cascode structure of claim 1, wherein the circuit comprises a high-voltage P-type field effect transistor.

3. The cascode structure of claim 1, wherein the second gate is switched by a switched capacitor or a clocked driver, via the circuit, to a protection voltage for biasing the second gate.

4. The cascode structure of claim 1, wherein the protection voltage is generated by a resistive divider.

5. The cascode structure of claim 4, wherein the resistive divider is a resistor ladder.

6. The cascode structure of claim 1, wherein the second gate is switched to a protection voltage for biasing the second gate by a diode clamp coupled to the second gate, wherein the diode clamp turns on as a drain of the cascode switching N-type field effect transistor device goes high.

7. The cascode structure of claim 1, wherein:
the switching path further comprises a second cascode switching N-type field effect transistor device in series with the main N-type field effect transistor switching device and the cascode switching N-type field effect transistor device and having a third gate; and
multiple protection voltages are used to clamp the second gate and the third gate during the off-state.

8. The cascode structure of claim 1, wherein:
the second gate is controlled by a diode clamp to a protection voltage; and
the first gate is coupled to a switching path clock via a delay element such that the main N-type field effect transistor switching device pulls down a source of the cascode switching N-type field effect transistor device during a high-to-low transition of a source terminal of the main N-type transistor.

9. The cascode structure of claim 8, wherein the delay element comprises a clocked delay circuit having digital logic and delay cells.

10. The cascode structure of claim 8, wherein the delay element comprises a resistor coupled to the first gate.

11. A cascode structure comprising:
a switching path comprising:
a main P-type field effect transistor switching device having a first gate; and
a cascode switching P-type field effect transistor device in series with the main P-type field effect transistor switching device and having a second gate; and
a circuit coupled between the first gate and the second gate, wherein the circuit is configured to:
in an off-state of the switching path, provide a high-impedance path between the first gate and the second gate, such that the second gate is switched to a protection voltage as high as a drain-to-source breakdown voltage of the main P-type field effect transistor switching device and such that the switching path is able to tolerate as high as the sum of the drain-to-source breakdown voltages of the main P-type field effect transistor switching device and the cascode switching P-type field effect transistor device; and
in an on-state of the switching path, provide a low-impedance path between the first gate and the second gate, such that a first voltage on the first gate and a second voltage on the second gate are approximately equal and the circuit is controlled by a voltage at a drain of the main P-type field effect transistor switching device.

12. The cascode structure of claim 11, wherein the circuit comprises a high-voltage N-type field effect transistor.

13. The cascode structure of claim 11, wherein the second gate is switched by a switched capacitor or a clocked driver, via the circuit, to a protection voltage for biasing the second gate.

14. The cascode structure of claim 11, wherein the protection voltage is generated by a resistive divider.

15. The cascode structure of claim 14, wherein the resistive divider is a resistor ladder.

16. The cascode structure of claim 11, wherein the second gate is switched to a protection voltage for biasing the second gate by a diode clamp coupled to the second gate, wherein the diode clamp turns on as a drain of the cascode switching N-type field effect transistor device goes high.

17. The cascode structure of claim 11, wherein:
the switching path further comprises a second cascode switching N-type field effect transistor device in series with the main N-type field effect transistor switching device and the cascode switching N-type field effect transistor device and having a third gate; and
multiple protection voltages are used to clamp the second gate and the third gate during the off-state.

18. A method in a cascode structure having a switching path comprising a main N-type field effect transistor switching device having a first gate and a cascode switching N-type field effect transistor device in series with the main N-type field effect transistor switching device and having a second gate, the method comprising, with a circuit coupled between the first gate and the second gate:
in an off-state of the switching path, providing a high-impedance path between the first gate and the second gate, such that the second gate is switched to a protection voltage as high as a drain-to-source breakdown voltage of the main N-type field effect transistor switching device and such that the switching path is able to tolerate as high as the sum of the drain-to-source breakdown voltages of the main N-type field effect transistor switching device and the cascode switching N-type field effect transistor device; and
in an on-state of the switching path, providing a low-impedance path between the first gate and the second gate, such that a first voltage on the first gate and a second voltage on the second gate are approximately equal and the circuit is controlled by a voltage at a drain of the main N-type field effect transistor switching device.

19. The method of claim 18, wherein the circuit comprises a high-voltage P-type field effect transistor.

20. The method of claim 18, further comprising switching the second gate by a switched capacitor or a clocked driver, via the circuit, to a protection voltage for biasing the second gate.

21. The method of claim 18, further comprising generating the protection voltage by a resistive divider.

22. The method of claim 21, wherein the resistive divider is a resistor ladder.

23. The method of claim 18, further comprising switching the second gate to a protection voltage for biasing the second gate by a diode clamp coupled to the second gate, wherein the diode clamp turns on as a drain of the cascode switching N-type field effect transistor device goes high.

24. The method of claim 18, wherein:
the switching path further comprises a second cascode switching N-type field effect transistor device in series with the main N-type field effect transistor switching device and the cascode switching N-type field effect transistor device and having a third gate; and
the method further comprises using multiple protection voltages to clamp the second gate and the third gate during the off-state.

25. The method of claim 18, further comprising:
controlling the second gate by a diode clamp to a protection voltage; and
wherein the first gate is coupled to a switching path clock via a delay element such that the main N-type field effect transistor switching device pulls down a source of the cascode switching N-type field effect transistor device during a high-to-low transition of a source terminal of the main N-type transistor.

26. The method of claim 25, wherein the delay element comprises a clocked delay circuit having digital logic and delay cells.

27. The method of claim 25, wherein the delay element comprises a resistor coupled to the first gate.

28. A method in a cascode structure having a switching path comprising a main P-type field effect transistor switching device having a first gate and a cascode switching P-type field effect transistor device in series with the main P-type field effect transistor switching device and having a second gate, the method comprising, with a circuit coupled between the first gate and the second gate:
in an off-state of the switching path, providing a high-impedance path between the first gate and the second gate, such that the second gate is switched to a protection voltage as high as a drain-to-source breakdown voltage of the main P-type field effect transistor switching device and such that the switching path is able to tolerate as high as the sum of the drain-to-source breakdown voltages of the main P-type field effect transistor switching device and the cascode switching P-type field effect transistor device; and
in an on-state of the switching path, providing a low-impedance path between the first gate and the second gate, such that a first voltage on the first gate and a second voltage on the second gate are approximately equal and the circuit is controlled by a voltage at a drain of the main P-type field effect transistor switching device.

29. The method of claim 28, wherein the circuit comprises a high-voltage N-type field effect transistor.

30. The method of claim 28, further comprising switching the second gate by a switched capacitor or a clocked driver, via the circuit, to a protection voltage for biasing the second gate.

31. The method of claim 28, further comprising generating the protection voltage by a resistive divider.

32. The method of claim 31, wherein the resistive divider is a resistor ladder.

33. The method of claim 28, further comprising switching the second gate to a protection voltage for biasing the second gate by a diode clamp coupled to the second gate, wherein the diode clamp turns on as a drain of the cascode switching P-type field effect transistor device goes high.

34. The method of claim 28, wherein:
the switching path further comprises a second cascode switching P-type field effect transistor device in series with the main P-type field effect transistor switching device and the cascode switching P-type field effect transistor device and having a third gate; and
the method further comprises using multiple protection voltages to clamp the second gate and the third gate during the off-state.
